(19) United States
(12) Patent Application Publication
(10) Pub. No.: US 2018/0356703 A1
(43) Pub. Date: Dec. 13, 2018

(54) DISPLAY DEVICE

(71) Applicant: BOE TECHNOLOGY GROUP CO., LTD., Beijing (CN)

(72) Inventors: Qian WANG, Beijing (CN); Xiaochuan CHEN, Beijing (CN); Wenqing ZHAO, Beijing (CN); Shengji YANG, Beijing (CN); Jian GAO, Beijing (CN)

(73) Assignee: BOE TECHNOLOGY GROUP CO., LTD., Beijing (CN)

(21) Appl. No.: 15/573,218

(22) PCT Filed: Jun. 14, 2017
(86) PCT No.: PCT/CN2017/088239

§ 371 Date: Nov. 10, 2017

(30) Foreign Application Priority Data
Aug. 30, 2016 (CN) 201610767920.5

(51) Int. Cl. G02F 1/29; H01L 27/32

(52) U.S. Cl. CPC G02F 1/29; G02F 2201/44; H01L 27/3232

(57) ABSTRACT

A display device includes a display panel; a collimation film structure and a liquid crystal lens structure sequentially arranged on a light exit side of the display panel; and an eye tracking unit for determining a position of a viewer in front of the liquid crystal lens structure. Specifically, the collimation film structure is configured to collimate light emitted from the display panel to form a collimated light. The liquid crystal lens structure is configured to redirect the collimated light towards the position determined by the eye tracking unit. By determining light emission directions of each sub-pixel in the display panel through eye tracking techniques and enabling the light converged on a position accepted by human eyes, light utilization is effectively improved and power consumption is reduced.

The present application is the U.S. national phase entry of PCT/CN2017/088239, with an international filling date of Jun. 14, 2017, which claims the benefit of priority from the Chinese patent application No. 201610767920.5 filed on Aug. 30, 2016, the disclosures of which are incorporated herein by reference.

### FIELD

The present disclosure relates to the field of display technologies, and in particular to a display device.

### BACKGROUND ART

At present, display technologies have hit a certain bottleneck, requiring an urgent breakthrough in terms of a larger display size, a finer resolution, a more flexible display manner, and so on.

Display panels usually comprise liquid crystal display (LCD) panels, electroluminescent display (ELD) panels, and the like.

### SUMMARY

Embodiments of the present disclosure provide a display device.

According to embodiments of the present disclosure, a display device is provided. The display device comprises: a display panel; a collimation film structure and a liquid crystal lens structure sequentially arranged on a light exit side of the display panel; and an eye tracking unit for determining a position of a viewer in front of the liquid crystal lens structure. Specifically, the collimation film structure is configured for collimating light emitted from the display panel to form a collimated light. Besides, the liquid crystal lens structure is configured for redirecting the collimated light towards the position determined by the eye tracking unit.

According to a possible implementation, in the display device provided by embodiments of the present disclosure, the display panel comprises a plurality of sub-pixels. Moreover, the liquid crystal lens structure is further configured for redirecting a portion of the collimated light corresponding to each sub-pixel towards the position determined by the eye tracking unit at a preset intensity. It should be pointed out herein that the term of “preset intensity” refers to any intensity that allows arrival at the position determined by the eye tracking unit with a gray scale required for image display.

According to a possible implementation, in the display device provided by embodiments of the present disclosure, the liquid crystal lens structure comprises: a first electrode and a second electrode arranged oppositely; a liquid crystal layer arranged between the first electrode and the second electrode; and a control unit. Furthermore, the control unit is configured for applying voltages to the first electrode and the second electrode and controlling liquid crystal molecules in the liquid crystal layer to deflect, so as to form a plurality of micro-prisms corresponding to each sub-pixel respectively. Optionally, the micro-prism comprises a wedge-shaped micro-prism.

According to a possible implementation, in the display device provided by embodiments of the present disclosure, the display panel comprises an electroluminescent display panel. In this case, the liquid crystal layer comprises two liquid crystal layers arranged in stack, namely a first liquid crystal layer and a second liquid crystal layer. Specifically, the first liquid crystal layer is configured for deflecting a first polarization direction of the collimated light and the second liquid crystal layer is configured for deflecting a second polarization direction of the collimated light. In particular, the first polarization direction and the second polarization direction are orthogonal to each other. Besides, in this embodiment, each wedge-shaped micro-prism comprises a first wedge-shaped micro-prism corresponding to the first liquid crystal layer and a second wedge-shaped micro-prism corresponding to the second liquid crystal layer.

According to a possible implementation, in the display device provided by embodiments of the present disclosure, the first wedge-shaped micro-prism and the second wedge-shaped micro-prism corresponding to a same sub-pixel unit have a same wedge angle.

According to a possible implementation, in the display device provided by embodiments of the present disclosure, the display panel comprises a liquid crystal display panel. In this case, the collimated light comprises linearly polarized collimated light. Besides, the liquid crystal lens structure is configured for deflecting a polarization direction of the linearly polarized light.

According to a possible implementation, in the display device provided by embodiments of the present disclosure, the collimated light has a divergence angle in a range of [−10°, +10° ].

According to a possible implementation, in the display device provided by embodiments of the present disclosure, the collimation film structure has an arc-shaped upper surface and a refractive index of 1.5.

According to a possible implementation, in the display device provided by embodiments of the present disclosure, a curvature radius and a camber for the arc-shaped upper surface of the collimation film structure are calculated through the following formula:

$$\{ \begin{matrix}{f}^{′} = \frac{r}{n - 1} \\ h = r - \sqrt{{r}^{2} - {( \frac{p}{2} )}^{2}}\end{matrix}$$

wherein r is the curvature radius for the arc-shaped upper surface of the collimation film structure, h is the camber for the arc-shaped upper surface of the collimation film structure, n is a refractive index of the collimation film structure, f′ is a focal distance of the collimation film structure, and p is the size for a light emitting surface of the collimation film structure across the display panel.

### BRIEF DESCRIPTION OF THE DRAWINGS

The following drawings are merely examples for illustrative purposes according to various disclosed embodiments and are not intended to limit the scope of the present invention.

FIG. 1 shows a schematic structure view for a display device according to an embodiment of the present disclosure;

FIG. 2 shows an optical path view when light passes through the collimation film structure according to an embodiment of the present disclosure;

FIG. 3 shows another optical path view when light passes through the collimation film structure according to an embodiment of the present disclosure;

FIG. 4 shows a schematic view for an angle range of light when sub-pixels on a left edge of the display panel are about to enter the left eye and the right eye of a person according to an embodiment of the present disclosure;

FIG. 5 shows an optical path view when the micro-prism stricture is equivalent to a wedge-shaped prism structure with a slope angle of 28° according to an embodiment of the present disclosure;

FIG. 6 shows an optical path view when light passes through the liquid crystal lens structure according to an embodiment of the present disclosure; and

FIG. 7 shows another optical path view when light passes through the liquid crystal lens structure according to an embodiment of the present disclosure.

### DETAILED DESCRIPTION OF THE EMBODIMENTS

Specific implementations of the display device provided by embodiments of the present disclosure will be described in detail with reference to the drawings.

In the drawings, thicknesses and shapes of each structure do not reflect a real ratio of the display device. Instead, they are only provided to schematically illustrate the content of the present disclosure.

When a person is watching directly in front of a display panel, human eyes can only passively accept part of the light, since light emitted from LCD panels, ELD panels or other panels are all divergent light, which results in a low light utilization. This problem has become more and more obvious with a continuous increase in the size of display panels.

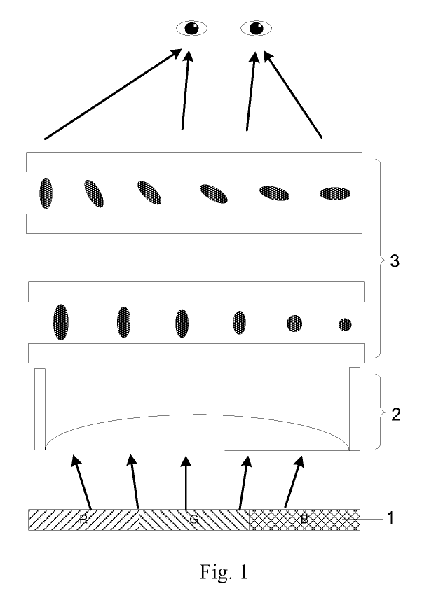

Embodiments of the present disclosure provide a display device. As shown in FIG. 1, the display device comprises: a display panel 1; a collimation film structure 2 and a liquid crystal lens structure 3 sequentially arranged on a light exit side of the display panel 1; and an eye tracking unit for determining a position of a viewer in front of the liquid crystal lens structure 3. In specific embodiments, the collimation film structure 2 is configured for collimating light emitted from the display panel 1 to form a collimated light. Besides, the liquid crystal lens structure 3 is configured for redirecting the collimated light towards the position determined by the eye tracking unit. Specifically, in the above process of redirection, the liquid crystal lens structure 3 can take the position determined by the eye tracking unit into consideration.

According to an embodiment of the present disclosure, the display device comprises: a display panel; a collimation film structure and a liquid crystal lens structure sequentially arranged on a light exit side of the display panel; and an eye tracking unit for determining a position of a viewer in front of the liquid crystal lens structure. Besides, the collimation film structure is configured for collimating light emitted from the display panel to form a collimated light, and the liquid crystal lens structure is configured for redirecting the collimated light towards the position determined by the eye tracking unit. By determining light emission directions of each sub-pixel in the display panel through eye tracking techniques and enabling the light converged on a position accepted by human eyes, light utilization is effectively improved and power consumption is reduced.

It should be noted that an initial display gray scale value for each sub-pixel in the display panel can be the same. This means that the sub-pixels in the display panel only display a pattern of image information, have a constant brightness, and do not display gray scale values corresponding to the image information. In this case, the gray scale value required by each sub-pixel can be modulated by means of the collimation film structure and the liquid crystal lens structure arranged on the light exit side of the display panel.

According to a specific implementation, in the display device provided by embodiments of the present disclosure, after passing through the collimation film structure, light emitted from the display panel (generally with a divergence angle in a range of [−80°, +80° ]) will become a collimated light having a smaller divergence angle. As an example, a range for the divergence angle of the collimated light can be [−10°, +10° ].

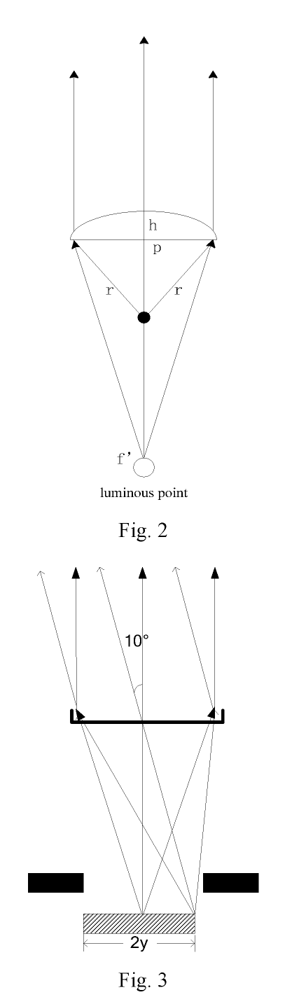

Furthermore, according to a specific implementation, in the display device provided by embodiments of the present disclosure, an upper surface of the collimation film structure 2 can have a shape of arc and a refractive index n of 1.5, as shown in FIG. 1 and FIG. 2. Besides, a barrier wall can be arranged at each side of the collimation film 2, so as to prevent part of the light being emitted out from an edge of the collimation film 2 and thus failing to be emitted into the liquid crystal lens structure. This facilitates a further improvement in the light utilization.

In FIG. 2, h represents the camber for the arc-shaped upper surface of the collimation film structure, r is the curvature radius for the arc-shaped upper surface of the collimation film structure, n is a refractive index of the collimation film structure, f′ is a focal distance of the collimation film structure, and p is a size for the collimation film structure. Specifically, p is a size for a light emitting surface across the display panel. If p=50 μm, and with a thickness of the display panel taken into consideration, f′=200 μm. This can be derived from the following formula wherein the curvature radius r=100 μm and the camber h=3.2 μm:

$$\{ \begin{matrix}{f}^{′} = \frac{r}{n - 1} \\ h = r - \sqrt{{r}^{2} - {( \frac{p}{2} )}^{2}}\end{matrix}$$

Besides, a light emitting spot of the display panel usually has a certain area. As shown in FIG. 3, with simulations performed by ZAMEX software, when the light emitting area 2y=p=50 μm, a range for the divergence angle of the exit light becomes [−10°, +10° ] after passing through the collimation film structure.

It should be noted that the collimation film structure in embodiments of the present disclosure can be any suitable lens structure for modulating light to form a collimated light, such as a combined lens structure. A surface shape and a refractive index for the lens structure are not limited to the arc shape as shown in the drawings of the present disclosure or the refractive index of 1.5 taken as an example. Obviously, lens structures having other different shapes and refractive indexes can also be applied in this application, which will not be limited here.

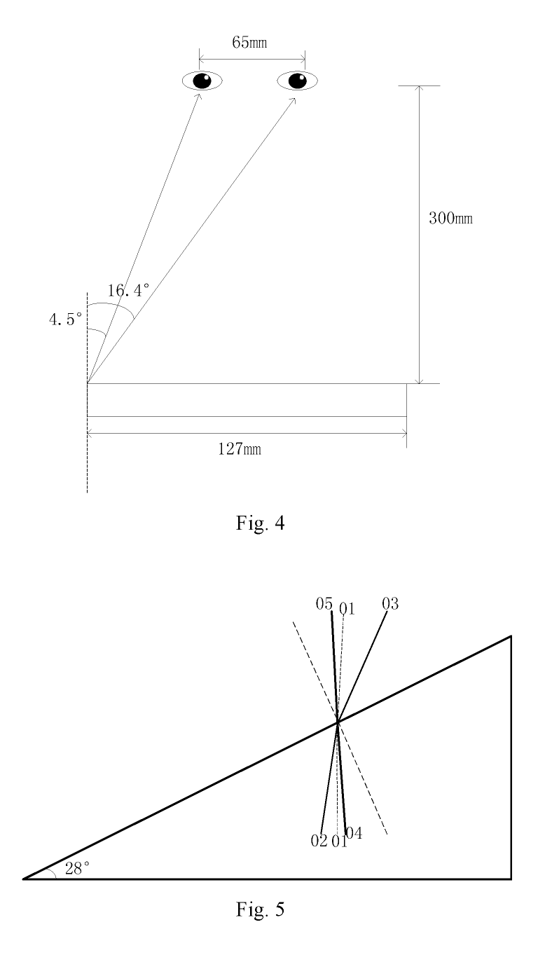

After passing through the collimation film structure, the exit light becomes a collimated light with a divergence angle in a range of [−10°, +10]. This light is then redirected via the liquid crystal lens structure and possibly subjected to a gray scale modulation. Incident light with a high degree of collimation is advantageous to a liquid crystal lens structure, as it makes the optical path to be calculated simpler and more optimized. However, in an actual situation, when human eyes want to see each and every sub-pixel in the entire display panel, light emitted from sub-pixels at an edge of the display panel can only enter human eyes at a certain angle. As shown in FIG. 4, a 5.5-inch screen is chosen as an example. An active region, i.e., region AA, has a long side of 127 mm. Typically, the viewing distance is 300 mm and an interpupillary distance of human eyes is 65 mm. When human eyes are in a central position, it requires an angle of 4.5° and an angle of 16.4° respectively for sub-pixels at a left edge of the display panel to enter the left eye and the right eye of a person. In other words, collimated light with a divergence angle in a range of [−10°, +10° ] cannot enter human eyes until it is subjected to a certain modulation (in particular, redirection) by the liquid crystal lens structure.

According to a specific implementation, in the display device provided by embodiments of the present disclosure, the display panel can be a liquid crystal display panel. In this case, only one liquid crystal lens is required, since light emitted from the liquid crystal display panel is linearly polarized light and has one polarization direction. Then, the liquid crystal lens structure can be configured for deflecting a polarization direction of the linearly polarized light emitted from the liquid crystal display panel.

According to a specific implementation, in the display device provided by embodiments of the present disclosure, the display panel can be chosen as an electroluminescent display panel. In this case, two liquid crystal lenses are required to act collaboratively for modulation, since light emitted from the electroluminescent display panel resembles natural light and can have different polarization directions. Then, as shown in FIG. 1, the liquid crystal lens structure 3 can be two liquid crystal lenses arranged in stack, namely a first liquid crystal lens and a second liquid crystal lens. Specifically, an optical clear adhesive is further provided between the first liquid crystal lens and the second liquid crystal lens, and a refractive index of the optical clear adhesive can be set as 1.5. Here, the first liquid crystal lens is configured for deflecting a first polarization direction of the collimated light and the second liquid crystal lens is configured for deflecting a second polarization direction of the collimated light. Furthermore, the first polarization direction and the second polarization direction are orthogonal to each other.

Optionally, according to a specific implementation, in the display device provided by embodiments of the present disclosure, the liquid crystal lens can comprise: a first electrode and a second electrode arranged oppositely; a liquid crystal layer arranged between the first electrode and the second electrode; and a control unit. Specifically, the control unit is configured for applying voltages to the first electrode and the second electrode and controlling liquid crystal molecules in the liquid crystal layer to deflect, so as to form a plurality of micro-prism structures corresponding to each sub-pixel respectively.

It should be noted that when the display panel is an electroluminescent display panel, initial alignment directions for liquid crystal molecules in the liquid crystal layer serving as the first liquid crystal and the second liquid crystal can be perpendicular to each other and parallel to the first electrode or the second electrode. In this way, the first liquid crystal lens only acts on light in the first polarization direction and the second liquid crystal lens only acts on light in the second polarization direction, wherein the first polarization direction and the second polarization direction are orthogonal to each other.

Furthermore, according to a specific implementation, in the display device provided by embodiments of the present disclosure, the micro-prism structure can be a wedge-shaped prism structure. For example, in FIG. 5, when the micro-prism structure is equivalent to a wedge-shaped prism structure with a slope angle of 28°, incident light 01 emitted upward vertically is deflected from a vertical direction by an angle of 16.8°, if a refractive index of the wedge-shaped prism structure is 1.5. Thereby, human eyes can see sub-pixels on edges of the display panel. Then, the divergence angle for the incident light falls within a range of [−10°, +10° ]. Besides, incident light 02 enclosing an angle of +10° with the vertical direction becomes exit light 03 enclosing an angle of 1° with the vertical direction, after being refracted by the wedge-shaped prism with a slope angle of 28°. Incident light 04 enclosing an angle of −10° with the vertical direction becomes exit light 05 enclosing an angle of 39° with the vertical direction, after being refracted by the wedge-shaped prism with a slope angle of 28°. In other words, the divergence angle for the incident light falls within a range of [−10°, +10° ], and the angle enclosed between the exit light 03 and the exit light 05 becomes 40°. In this way, it can cover the interpupillary distance of human eyes, i.e., 65 mm, after passing through a viewing distance of 300 mm. Then, the gray scale value displayed by the sub-pixels corresponding to the micro-prism structure is the maximum gray scale value.

According to a specific implementation, in the display device provided by embodiments of the present disclosure, in a same sub-pixel, two wedge-shaped prism structures corresponding to the same sub-pixel and formed respectively in two liquid crystal lenses arranged in stack can have a same slope angle. In this way, the optical path to be calculated is simpler and more optimized, which allows light to enter human eyes more accurately.

According to a specific implementation, in the display device provided by embodiments of the present disclosure, in a region between the position determined by the eye tracking unit and the display panel, liquid crystal molecules corresponding to the sub-pixels having the maximum gray scale value to be displayed do not deflect. In other words, micro-prism structures are not formed in a region where the sub-pixels having the maximum gray scale value to be displayed are located.

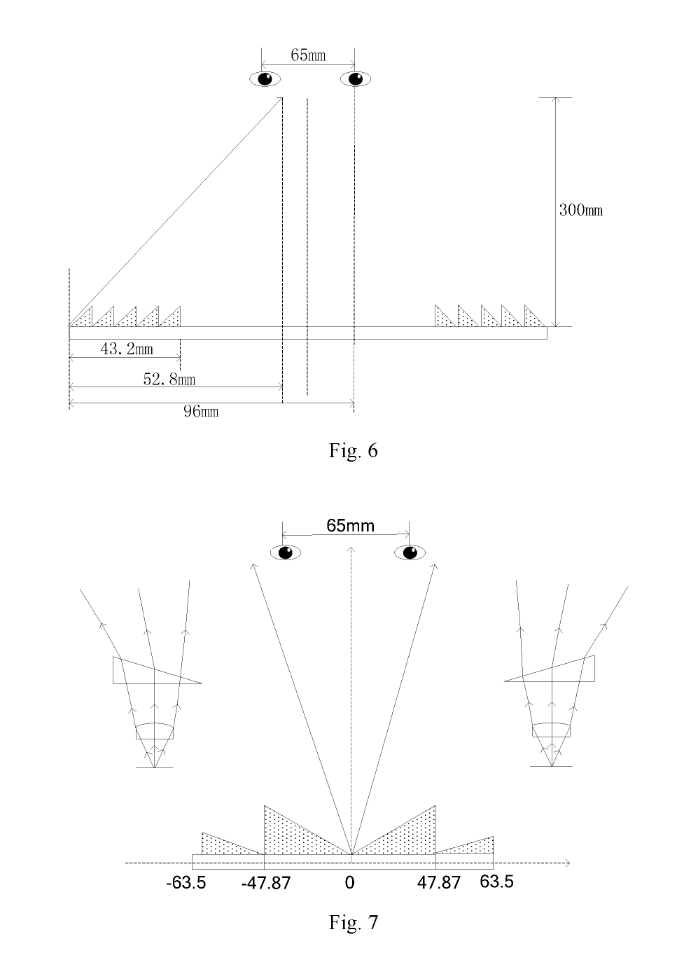

For example, in FIG. 6, when all sub-pixels of the entire display panel have the maximum gray scale value to be displayed, light entering human eyes with a deflection from the vertical direction by 10° after being modulated by the liquid crystal lens structure is taken as a reference. In this case, it is only required to arrange the liquid crystal lens structure within a length range of about 43.2 mm from the left to the right of the display panel. This is derived from tan 10° *300 mm=52.8 mm, and 96 mm-52.8 mm=43.2 mm. Liquid crystal lens structures in other positions do not operate. In this way, human eyes can see all the sub-pixels of the entire display panel. Accordingly, FIG. 6 shows that slope angles of liquid crystal lens structures disposed at the right side of the display panel are all tilted leftwards, and slope angles of liquid crystal lens structures disposed at the left side of the display panel are all tilted rightwards.

For example, in FIG. 7, in case all the sub-pixels of the entire display panel have the minimum gray scale value to be displayed, if the incident light has a divergence angle of [−10°, +10] to take the right half of the display panel as an example, the liquid crystal lens structure needs to adjust the light such that the light does not enter human eyes, i.e., to ensure that the light does not enter the right eye. Then, if a liquid crystal lens structure with a slope angle of 14° is used, the light deflected leftwards by 10° after the deflection by the liquid crystal lens structure will enclose an angle of 2.93° with the vertical direction. Accordingly, a liquid crystal lens structure with a slope angle of 14° is arranged beyond a range of 47.87 mm away from the center of the display panel. This is derived from tan 2.93° *300 mm=15.72 mm. Further, a liquid crystal lens structure with a slope angle of 14° needs to be arranged there. Continuously, to take the right half of the display panel as an example, with central pixels of the display panel as a reference, the leftmost light encloses an angle of 6.48° with the vertical direction, after being deflected by a liquid crystal lens structure with a slope angle of 30°. In this way, it can be ensured that the leftmost light does not enter the right eye. This is derived from tan 6.48° *300 mm=34 mm, and 34 mm is greater than half the interpapillary distance of 32.5 mm. That is, in the display panel, a liquid crystal lens structure with a slope angle of 30° needs to be arranged in a range of 47.87 mm away from the edge of the display panel. Then, human eyes cannot see the sub-pixels of the entire display panel at all, I.e., the gray scale value is 0. Accordingly, FIG. 7 shows that slope angles of the liquid crystal lens structures disposed in the right half of the display panel are all tilted rightwards, and slope angles of the liquid crystal lens structures disposed in the left half of the display panel are all tilted leftwards.

It should be noted that when the gray scale value to be displayed by all the sub-pixels of the entire display panel is an intermediate gray scale value, and the display panel is an electroluminescent display panel, it is only required that the first liquid crystal lens or the second liquid crystal lens of the two liquid crystal lenses arranged in stack is capable of operating.

For the display device provided in embodiments of the present disclosure, all other indispensable components should be understood by one having ordinary skills in the art. This will not be described herein for simplicity, and should not be construed as limiting the present disclosure. For implementations of the display device, implementations of the display device can be referred to, which will not be repeated here for simplicity.

Embodiments of this disclosure provide a display device, comprising: a display panel; a collimation film structure and a liquid crystal lens structure sequentially arranged on a light exit side of the display panel; and an eye tracking unit for determining a position of a viewer in front of the liquid crystal lens structure. Specifically, the collimation film structure is configured for collimating light emitted from the display panel to form a collimated light, and the liquid crystal lens structure is configured for redirecting the collimated light towards the position determined by the eye tracking unit. According to the present disclosure, by determining light emission directions of each sub-pixel in the display panel through eye tracking techniques and enabling the light converged on a position accepted by human eyes, light utilization is effectively improved and power consumption is reduced.

Obviously, those skilled in the art can make various modifications and variations to the present disclosure without departing from spirits and scopes of the present disclosure. Thus, if these modifications and variations to the present disclosure fall within the scopes of the claims in the present disclosure and the equivalent techniques thereof, the present disclosure is intended to include them too.

1. A display device, comprising:
a display panel;
a collimation film structure and a liquid crystal lens structure sequentially arranged on a light exit side of the display panel; and
an eye tracking unit for determining a position of a viewer in front of the liquid crystal lens structure, wherein
the collimation film structure is configured to collimate light emitted from the display panel to form a collimated light, and
the liquid crystal lens structure is configured to redirect the collimated light towards the position determined by the eye tracking unit.

2. The display device according to claim 1, wherein
the display panel comprises a plurality of sub-pixels, and
the liquid crystal lens structure is further configured to redirect a portion of the collimated light corresponding to each sub-pixel towards the position determined by the eye tracking unit at a preset intensity.

3. The display device according to claim 2, wherein
the liquid crystal lens structure comprises:
a first electrode and a second electrode arranged oppositely;
a liquid crystal layer arranged between the first electrode and the second electrode; and
a control unit, wherein
the control unit is configured to apply voltages to the first electrode and the second electrode and control liquid crystal molecules in the liquid crystal layer to deflect, so as to form a plurality of micro-prisms corresponding to each sub-pixel respectively.

4. The display device according to claim 3, wherein
the micro-prism comprises a wedge-shaped micro-prism.

5. The display device according to claim 4, wherein
the display panel comprises an electroluminescent display panel,
the liquid crystal layer comprises a first liquid crystal layer and a second liquid crystal layer arranged in stack,
the first liquid crystal layer is configured to deflect a first polarization direction of the collimated light, and the second liquid crystal layer is configured to deflect a second polarization direction of the collimated light, the first polarization direction and the second polarization direction being orthogonal to each other, and
each wedge-shaped micro-prism comprises a first wedge-shaped micro-prism corresponding to the first liquid crystal layer and a second wedge-shaped micro-prism corresponding to the second liquid crystal layer.

6. The display device according to claim 4, wherein
the first wedge-shaped micro-prism and the second wedge-shaped micro-prism corresponding to a same sub-pixel unit have a same wedge angle.

7. The display device according to claim 4, wherein
the display panel comprises a liquid crystal display panel,
the collimated light comprises linearly polarized collimated light, and
the liquid crystal lens structure is configured to deflect a polarization direction of the linearly polarized light.

8. The display device according to claim 1, wherein the collimated light has a divergence angle in a range of [−10°, +10°].

9. The display device according to claim 8, wherein the collimation film structure has an arc-shaped upper surface and a refractive index of 1.5.

10. The display device according to claim 9, wherein a curvature radius and a camber for the arc-shaped upper surface of the collimation film structure are calculated through the following formula:
$$\{ \begin{matrix}{f}^{′} = \frac{r}{n - 1} \\ h = r - \sqrt{{r}^{2} - {( \frac{p}{2} )}^{2}}\end{matrix}$$
wherein r is the curvature radius for the arc-shaped upper surface of the collimation film structure, h is the camber for the arc-shaped upper surface of the collimation film structure, n is a refractive index of the collimation film structure, f′ is a focal distance of the collimation film structure, and p is a size for a light emitting surface of the collimation film structure across the display panel.
